(19) United States
(12) Patent Application Publication
(10) Pub. No.: US 2015/0306728 A1
(43) Pub. Date: Oct. 29, 2015

(54) SYSTEMS FOR, METHODS OF, AND APPARATUS FOR PROCESSING SUBSTRATE SURFACES

(71) Applicant: Silicon Quest International, Incorporated, San Jose, CA (US)

(72) Inventors: Yevsey SENDERZON, San Jose, CA (US); Michael LYU, San Jose, CA (US)

(73) Assignee: SILICON QUEST INTERNATIONAL, INCORPORATED, San Jose, CA (US)

(21) Appl. No.: 14/259,449

(22) Filed: Apr. 23, 2014

(51) Int. Cl. B24B 37/08; B24B 37/28; H01L 21/304; B24B 37/04

(52) U.S. Cl. CPC B24B 37/08; B24B 37/042; B24B 37/28; H01L 21/304

(57) ABSTRACT

The following description pertains to processing substrates using processes such as, but not limited to, polishing or lapping. Descriptions of systems, methods, and apparatuses according to one or more embodiments of the present invention are presented.

### BACKGROUND

One or more embodiments of the present invention pertain to processing substrates such as those used for the fabrication of electronic devices, optoelectronic devices, optical devices, transistors, and/or integrated circuits.

The present inventors have made one or more discoveries that may be pertinent to processing the surface of substrates using processes such as, but not limited to, polishing and lapping.

### SUMMARY

One aspect of the present invention pertains to a substrate holder for a first substrate and a second substrate.

Another aspect of the present invention pertains to a system comprising a substrate holder for processing substrates.

Another aspect of the present invention pertains to a method comprising using a substrate holder for processing substrates.

It is to be understood that the invention is not limited in its application to the details of construction and to the arrangements of the components set forth in the following description. The invention is capable of other embodiments and of being practiced and carried out in various ways. In addition, it is to be understood that the phraseology and terminology employed herein are for the purpose of description and should not be regarded as limiting.

### BRIEF DESCRIPTION OF THE DRAWINGS

FIG. 1 is a cross-section side edge view of an example of a substrate holder according to an embodiment of the present invention.

FIG. 2 is a view of a first side of a substrate holder according to one embodiment of the present invention.

FIG. 3 is a cross-section side view of a substrate holder according to one embodiment of the present invention with substrates shown in broken lines.

FIG. 4 is a view of a first side of a substrate holder according to one embodiment of the present invention with substrate shown in broken lines.

FIG. 5 is a side view of a section of a system according to one embodiment of the present invention with substrates shown in broken lines.

FIG. 6 is a top view of a section of a system according to one embodiment of the present invention with substrates shown in broken lines.

FIG. 7 is an illustration of the spin and rotation directions subjected to the work surface of a substrate held by a substrate holder in a system according to one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding embodiments of the present invention.

### DESCRIPTION

In the following description of the figures, identical reference numerals have been used when designating substantially identical elements or processes that are common to the figures.

For the following defined terms, these definitions shall be applied, unless a different definition is given in the claims or elsewhere in this specification. All numeric values are herein defined as being modified by the term “about,” whether or not explicitly indicated. The term “about” generally refers to a range of numbers that a person of ordinary skill in the art would consider equivalent to the stated value to produce substantially the same properties, function, result, etc. A numerical range indicated by a low value and a high value is defined to include all numbers subsumed within the numerical range and all subranges subsumed within the numerical range. As an example, the range 10 to 15 includes, but is not limited to, 10, 10.1, 10.47, 11, 11.75 to 12.2, 12.5, 13 to 13.8, 14, 14.025, and 15.

For the present disclosure, the term “substrate” refers to a workpiece for processes, apparatuses, and/or systems according to one or more embodiments of the present invention. The substrate is a solid at ambient conditions. The substrate may be used for applications such as, but not limited to, forming and/or supporting devices such as integrated circuits, electronic devices, optical devices, optoelectronic devices, and for other uses. Examples of substrates include, but are not limited to, wafers, semiconductor wafers, silicon wafers, compound semiconductor wafers, aluminum oxide wafers, sapphire wafers, and quartz wafers.

The term “work surface” as used herein is defined as a surface of the substrate that is being or will be processed such as by polishing, lapping, or grinding.

The term “horizontal” as used herein is defined as a plane parallel to the plane or surface of the substrate or surface of the wafer, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

Flatness is quantified in part by a Total Thickness Variation measurement (TTV) and/or Site Total Indicated Reading (STIR). TTV is the difference between the maximum and minimum thicknesses of the wafer. STIR is the sum of the maximum positive and negative deviations of the surface in a small area of the wafer from a reference plane which is parallel to the back surface of the wafer and intersects the front surface at the center of the local site. Total thickness variation in the wafer is an indicator of the quality of the polish of the wafer.

The order of execution or performance of the operations or the processes in embodiments of the invention illustrated and described herein is not essential, unless otherwise specified. That is, the operations or the processes may be performed in any order, unless otherwise specified, and embodiments of the invention may include additional or fewer operations or processes than those disclosed herein. For example, it is contemplated that executing or performing a particular operation or process before, contemporaneously with, or after another operation or process is within the scope of aspects of the invention.

Embodiments of the present invention will be discussed below primarily in the context of polishing or lapping substrates such as semiconductor wafers used for fabricating electronic devices, optoelectronic devices, and/or optical devices for applications such as, but not limited to, integrated circuits, light emitting diodes, high brightness light emitting diodes, transistors, and high-power transistors; however, it is to be understood that embodiments in accordance with the present invention may be used for other types of substrates, materials other than semiconductors, and processes other than polishing or lapping.

One or more embodiments of the present invention pertain to methods and/or apparatus for increasing the usage of substrate processing systems designed for simultaneous double side processing of substrates for processes such as polishing and lapping. Systems used for simultaneous double-side polishing or lapping substrates are configured so as to hold one or more substrates between two polishing or lapping surfaces so that both sides of the substrate are polished or lapped. According to one or more embodiments of the present invention, a system designed for simultaneous double side processing of substrates is converted to processing a single side of the substrates using a substrate holder according to one or more embodiments of the present invention. Consequently, a system designed for simultaneous double side processing of substrates can be used for either single side processing, which can also have a high substrate throughput, or double-side processing of substrates by using substrate holders according to embodiments of the present invention or standard substrate holders, respectively.

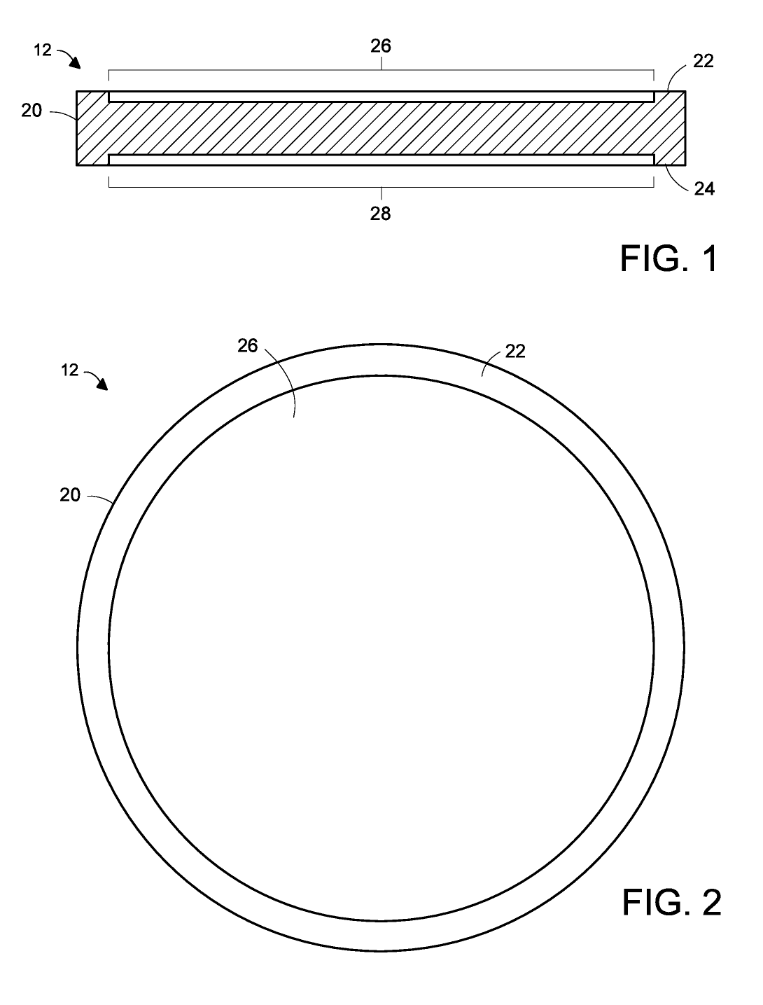

Reference is now made to FIGS. 1, 2, 3, and 4. FIG. 1 shows a cross-section side view of a substrate holder 12 according to one or more embodiments of the present invention. Substrate holder 12 is configured so as to hold two or more substrates. Each of the substrates has a work surface substantially as defined above. Substrate holder 12 comprises a substantially rigid body 20 having a first side 22 and a second side 24 on opposite sides of body 20 so as to hold a first substrate (first substrate not shown in FIG. 1) on first side 22 and a second substrate (second substrate not shown in FIG. 1) on second side 24 so that the work surface of the first substrate faces away from and is parallel to the work surface of the second substrate. More specifically, first side 22 has a first recessed area 26 sized to receive the first substrate, second side 24 has a second recessed area 28 sized to receive the second substrate.

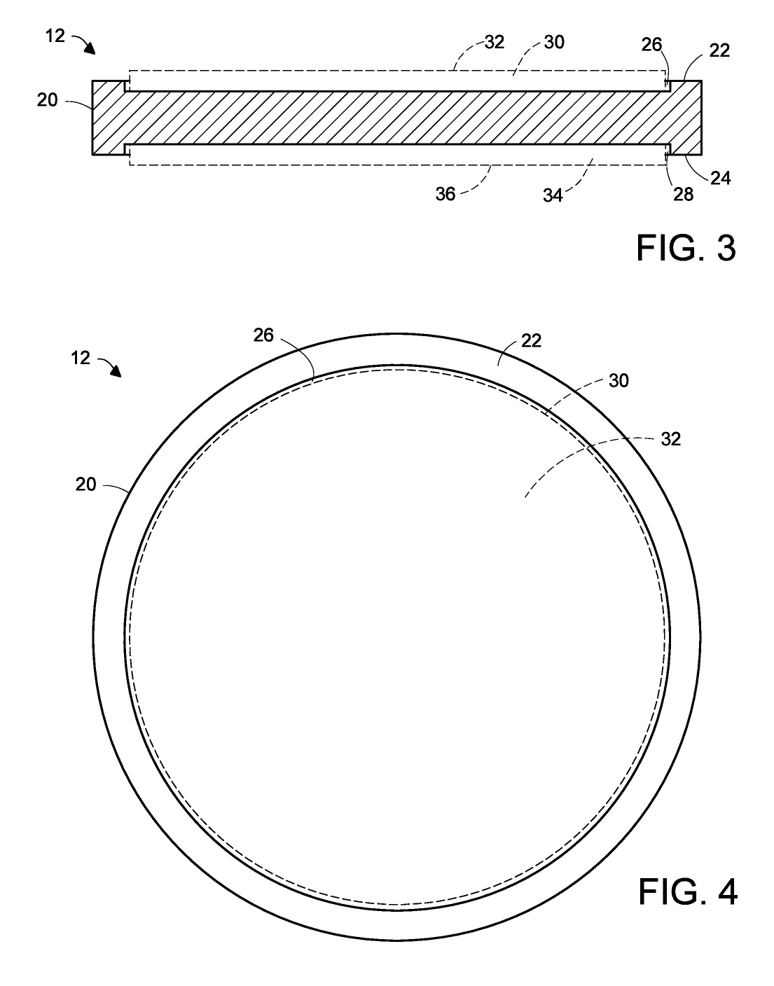

FIG. 2 shows first side 22 of wafer holder 12. FIG. 3 shows a cross-section side view of wafer holder 12 that is the same as that shown in FIG. 1. FIG. 3 further illustrates placement of a first substrate 30 (shown in broken lines) in recessed area 26 of first surface 22 and placement of a second substrate 34 (shown in broken lines) in recessed area 28 of second surface 24. First substrate 30 has work surface 32 facing the opposite direction of work surface 36 of second substrate 34. FIG. 4 shows a plan view of first side 22 of wafer holder 12 with first substrate 30 disposed in recessed area 26 with work surface 32 of first substrate 30 facing away from first surface 22.

According to one embodiment of the present invention, substrate holder 12 is disk shaped. More specifically, substrate holder 12 has a substantially circular periphery which may result from having an actual circular outer diameter or an outer diameter defined by multiple flat sides such as for, but not limited to, a pentagon, hexagon, octagon, etc., which approximate a circular diameter. According to one or more embodiments of the present invention, the width or the outer diameter of substrate holder 12 is greater than the diameter of the first substrate and of the second substrate. In other words, the outer edge of substrate holder 12 extends beyond the outer edge of the substrates sufficiently to reduce possible physical damage to the edge of the substrate that could result from contact with other objects, such as, but not limited to, other substrate holders, other substrates, and barriers of processing systems like walls.

Substrate holder 12 may be made of a variety of materials. According to one embodiment of the present invention, substrate holder 12 is metallic and comprises a metal or a metal alloy. According to one or more embodiments of the present invention, substrate holder 12 comprises material such as, but not limited to, aluminum, aluminum alloy, nickel, nickel alloy, molybdenum, molybdenum alloy, steel, stainless steel, titanium, titanium alloy, tantalum, tantalum alloy, or combinations thereof. According to one or more embodiments of the present invention, substrate holder 12 comprises material such as but not limited to polymer, plastic, ceramic, and/or other non-metallic materials.

According to one or more embodiments of substrate holder 12, first recessed area 26 and the second recessed area 28 may have shapes and dimensions to accommodate a variety of substrate sizes. Generally, first recessed area 26 and second recessed area 28 are shaped and sized so that the substrates can be placed in the recessed area. According to one embodiment of the present invention, the depth of first recessed area 26 is not greater than the thickness of the first substrate prior to lapping or polishing and the depth of the second recessed area 28 is not greater than the thickness of the second substrate prior to lapping or polishing.

Another embodiment of the present invention is a substrate holder for a first substrate and a second substrate, the first substrate and the second substrate each have a work surface. The substrate holder comprises a metal disk-shaped body having a first side and a second side on opposite sides of the body. The first side has a first recessed area sized to receive the first substrate. The depth of the first recessed area is selected to be not greater than the thickness of the first substrate. The second side has a second recessed area sized to receive the second substrate. The depth of the second recessed area is selected to be not greater than the thickness of the second substrate. The substrate holder holds the first substrate on the first side and the second substrate on the second side so that the work surface of the first substrate faces away from and is parallel to the work surface of the second substrate.

Substrate holder 12, such as that described in FIG. 1, holds a substrate on a first side and holds a substrate on a second side. However, for one or more embodiments of the present invention, the substrate holder may be configured to hold more than one substrate on one or both sides. One embodiment of the present invention comprises a substrate holder for two or more substrates with each of the two or more substrates having a work surface. The substrate holder comprises a substantially rigid body having a first side and a second side on opposite sides of the body. The first side has one or more recessed areas to receive one or more of the two or more substrates. The second side has one or more recessed areas to receive one or more of the two or more substrates. The work surface of the one or more substrates on the first side faces the opposite direction of the work surface of the one or more substrates on the second side.

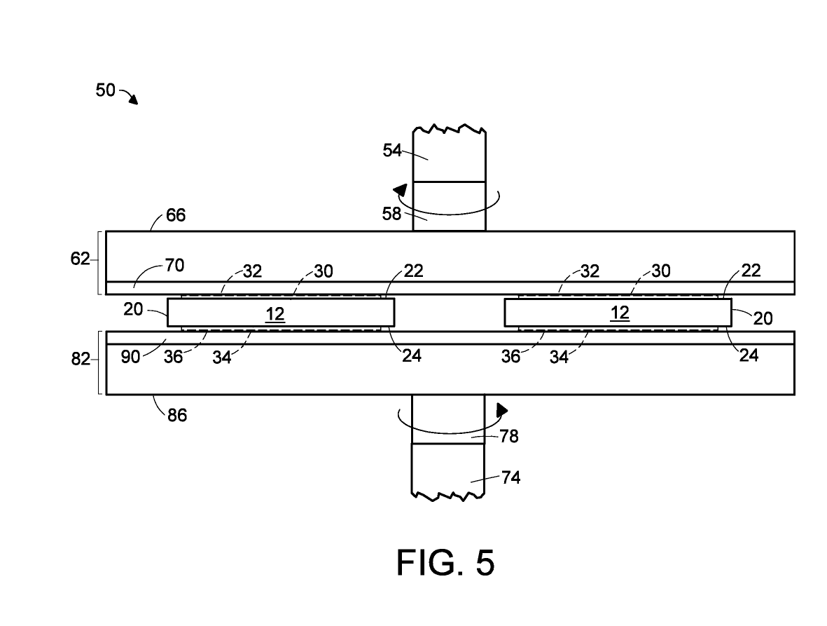

One aspect of the present invention pertains to a system for processing a surface of substrates using processes such as polishing or lapping. FIG. 5 shows a side view of a partial diagram of a system 50 according to one embodiment of the present invention. System 50 comprises at least one substrate holder 12 wherein substrate holder 12 is substantially as described above. System 50 further comprises a first housing section 54, a rotary coupling 58, and a first polishing or lapping tool 62. Rotary coupling 58 connects the first housing section 54 with the first polishing or lapping tool 62. According to one or more embodiments of the present invention, first polishing or lapping tool 62 comprises a first polishing or lapping pad holder 66 and a first polishing or lapping pad 70. System 50 also comprises a second housing section 74, a rotary coupling 78, and a second polishing or lapping tool 82. Rotary coupling 78 connects the second housing section 74 with the first polishing or lapping tool 82. According to one or more embodiments of the present invention, second polishing or lapping tool 82 comprises a second polishing or lapping pad holder 86 and a second polishing or lapping pad 90.

First polishing or lapping tool 62 and second polishing or lapping tool 82 are spaced apart and disposed opposite so that they face each other and are parallel to each other so as to form a polishing or lapping zone to receive the least one substrate holder 12. In other words, the polishing zone is bounded at least in part by the polishing or lapping surface of first polishing or lapping tool 62 and by the polishing or lapping surface of second polishing or lapping tool 82. The at least one substrate holder 12 has a first substrate 30 on first surface 22 and a second substrate 34 on second surface 24; they are placed between first polishing or lapping tool 62 and second polishing or lapping tool 82. Work surface 32 of first substrate 30 contacts the polishing or lapping surface of first polishing or lapping tool 62. Work surface 36 of second substrate 34 contacts the polishing or lapping surface of second polishing or lapping tool 82 so that simultaneous polishing or lapping of work surface 32 of first substrate 30 and work surface 36 of second substrate 36 is effected by rotating first polishing or lapping tool 62 and/or rotating second polishing or lapping tool 82.

According to one or more embodiments of the present invention, rotary coupling 58 imparts rotary motion to first polishing or lapping tool 62 and rotary coupling 78 imparts rotary motion to second polishing or lapping tool 82. FIG. 5 shows, as an example illustration, that the rotary motion of first polishing or lapping tool 62 is in the opposite direction of the rotary motion of second polishing or lapping tool 82. It is to be understood that other embodiments of the present invention may use other rotary motion selections. Optionally, first polishing or lapping tool 62 may be rotated in the same direction as second polishing or lapping tool 82. Optionally, only one of the polishing or lapping tools may be rotated while the other remains fixed.

FIG. 5 shows system 50 with two substrate holders 12 with wafers for the purpose of illustration. It is to be understood that one or more embodiments of the present invention may have system 50 processing with only one substrate holder 12 with wafers or may have system 50 processing with two or more than two substrate holders 12 with wafers. Systems according to one or more embodiments of the present invention may have dimensions so as to receive one substrate holder for processing substrates. Other systems according to one or more embodiments of the present invention may have dimensions so as to receive two or more than two substrate holders for processing substrates.

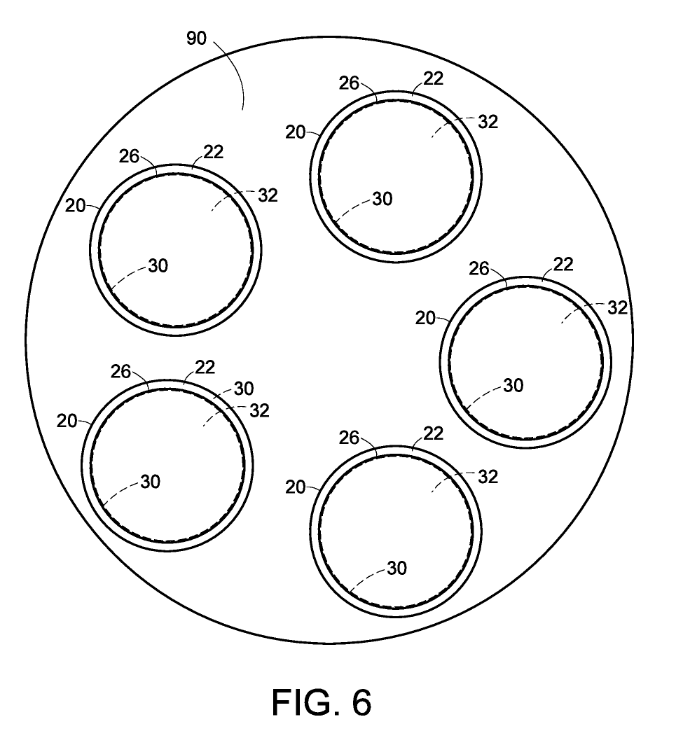

Reference is now made to FIG. 6 which provides an illustration of a partial system 50 according to one embodiment of the present invention. More specifically, FIG. 6 shows a top view of second polishing or lapping pad 90 supporting five substrate holders showing first sides 22 with first substrates 30. The number of substrate holders 12 used in system 50 will depend on factors such as the size of the substrate and the size of the polishing or lapping tools.

According to one or more embodiments of the present invention, such as the embodiments illustrated in FIGS. 5 and 6, substrate holders 12 are not fixedly attached. More specifically, substrate holders 12 in system 50 freely move about under the influence of momentum transferred from surface contact with first polishing or lapping tool 62 and/or second polishing or lapping tool 82. Because of the momentum transfer to substrate holder 12, the work surfaces of the attached substrates are subjected to three different spin motions while contacting the polishing or lapping surface.

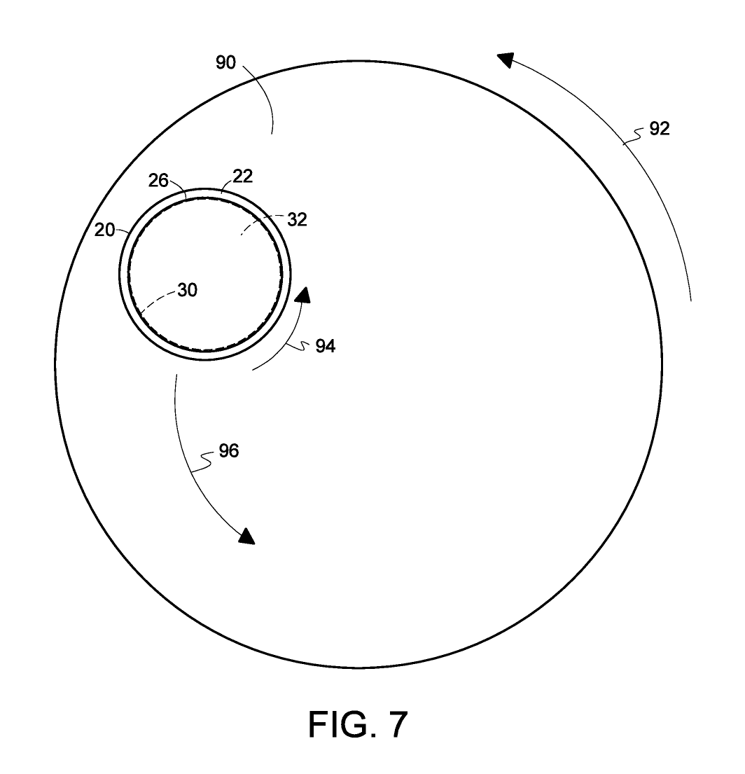

Reference is now made to FIG. 7. FIG. 7 illustrates three spin motions that a work surface of a substrate is subjected to during polishing or lapping according to one or more embodiments of the present invention. More specifically, FIG. 7 shows a top view of a partial system 50 which includes second polishing or lapping pad 90 supporting a substrate holder showing first surface 22 and first substrate 30. Second substrate 34 cannot be seen because it is between body 20 of the substrate holder and second polishing or lapping pad 90. Arrow 92 indicates the spin direction of second polishing or lapping pad 90. Arrow 94 indicates the spin direction of the substrate holder. Arrow 96 indicates the direction of rotation of the substrate holder around the center of second polishing or lapping pad 90.

As an option, system 50 may further comprise a distributor (distributor not shown in figures) to provide a slurry such as a chemical mechanical polishing slurry, an abrasive material, an etchant, a lubricant such as oil or other materials that may be used for polishing and/or lapping processes.

As an option for system 50, the substrates can be releasably attached to the substrate holder with a binder applied between the substrate holder and the substrate. The binder may be a material such as an adhesive, such as a resin, such as a wax, or other material.

Another aspect of the present invention pertains to a method of simultaneously processing a work surface of a first substrate and a work surface of a second substrate using processes such as polishing or lapping. One embodiment of the present invention comprises a method which comprises providing a substrate holder 12 substantially as described above. The method comprises providing an apparatus having a first polishing or lapping surface and a second polishing or lapping surface disposed opposite and parallel to the first polishing or lapping surface. The method comprises disposing the first substrate in contact with the first side of the substrate holder and disposing the second substrate in contact with the second side of the substrate holder. The method also comprises contacting the first polishing surface with the work surface of the first substrate while the first substrate is held on the first side of the holding surface to polish or lap the first substrate while also contacting the second polishing surface with the work surface of the second substrate while the second substrate is held with the second holding surface to polish or lap the second substrate.

The method further comprises rotating the first polishing or lapping surface while contacting the first substrate and/or rotating the second polishing or lapping surface while contacting the second substrate.

According to one or more embodiments of the present invention, the method comprises rotating the first polishing or lapping surface while contacting the first substrate and rotating the second polishing or lapping surface while contacting the second substrate, and allowing momentum transferred from the first polishing or lapping surface and the second polishing or lapping surface to freely rotate and/or spin the substrate holder and the substrate.

As an option for one or more embodiments of the present invention, the method may further comprise using a slurry such as a chemical mechanical polishing slurry; an abrasive material; an etchant, a lubricant such as oil or other materials that may be used for polishing and/or lapping processes.

A variety of substrates can be processed by methods according to embodiments of the present invention. According to one embodiment of the present invention, the method includes the first substrate and the second substrate comprising semiconductor wafers for fabricating electronic and/or optical devices. According to another embodiment of the present invention, the method includes the first substrate and the second substrate comprising silicon wafers for fabricating electronic devices.

Wafers produced according to one or more embodiments of the present invention meet predetermined specifications for properties such as TTV and roughness. Typically, wafers produced according to one or more embodiments of the present invention have total thickness variation of about 1 μm (for 100 mm to 200 mm diameter wafers) and surface roughness of about 0.1-0.3 nanometers.

Wafer holders according to one or more embodiments of the present invention can be used with a variety of simultaneous double-side substrate processing systems. Examples of possible double side substrate processing systems suitable for one or more embodiments of the present invention include, but are not limited to, systems described in U.S. Pat. No. 6,062,949, U.S. Pat. No. 6,113,478, U.S. Pat. No. 6,227,944, and U.S. Pat. No. 6,296,553. The content of U.S. Pat. No. 6,062,949, U.S. Pat. No. 6,113,478, U.S. Pat. No. 6,227,944, and U.S. Pat. No. 6,296,553 are incorporated herein by this reference for all purposes.

In the foregoing specification, the invention has been described with reference to specific embodiments; however, one of ordinary skill in the art appreciates that various modifications and changes can be made without departing from the scope of the present invention as set forth in the claims below. Accordingly, the specification is to be regarded in an illustrative, rather than a restrictive sense, and all such modifications are intended to be included within the scope of the present invention.

Benefits, other advantages, and solutions to problems have been described above with regard to specific embodiments; however, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements, but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

What is claimed is:

1. A substrate holder for a first substrate and a second substrate, the first substrate and the second substrate each having a work surface, the substrate holder comprising:
a substantially rigid body having a first side and a second side on opposite sides of the body so as to hold the first substrate on the first side and the second substrate on the second side so that the work surface of the first substrate faces away from and is parallel to the work surface of the second substrate; the first side having a first recessed area sized to receive the first substrate, the second side having a second recessed area sized to receive the second substrate.

2. The substrate holder of claim 1, wherein the substrate holder is disk shaped.

3. The substrate holder of claim 1, wherein the substrate holder is disk shaped and has a diameter greater than the diameter of the first substrate and of the second substrate.

4. The substrate holder of claim 1, wherein the holder comprises a metal or a metal alloy.

5. The substrate holder of claim 1, wherein the holder comprises aluminum, aluminum alloy, nickel, nickel alloy, molybdenum, molybdenum alloy, steel, stainless steel, titanium, titanium alloy, tantalum, tantalum alloy, or combinations thereof.

6. The substrate holder of claim 1, wherein the depth of the first recessed area is not greater than the thickness of the first substrate and the depth of the second recessed area is not greater than the thickness of the second substrate.

7. A system for simultaneously polishing or lapping a first substrate and a second substrate, the system comprising:
a substrate holder according to claim 1; and
an apparatus having a first polishing or lapping tool and a second polishing or lapping tool disposed opposite and parallel to the first polishing or lapping tool to receive the substrate holder.

8. The system of claim 7, wherein the apparatus comprises one or more rotary couplings to impart rotary motion to the first polishing or lapping tool and to impart rotary motion to the second polishing or lapping tool.

9. The system of claim 7, wherein the substrate holder is disk shaped.

10. The system of claim 7, wherein the holder comprises a metal or metal alloy.

11. The system of claim 7, wherein the holder comprises aluminum, aluminum alloy, molybdenum, molybdenum alloy, nickel, nickel alloy, steel, stainless steel, titanium, titanium alloy, tantalum, tantalum alloy, or combinations thereof.

12. The system of claim 7, wherein the apparatus comprises one or more rotary couplings to impart rotary motion to the first polishing or lapping tool and to impart rotary motion to the second polishing or lapping tool, the substrate holder is disk shaped and rotated by momentum from the first polishing or lapping tool and/or the second polishing or lapping tool.

13. The system of claim 7, wherein the holder is not fixedly attached.

14. The system of claim 7, wherein the system is has dimensions so as to receive two or more substrate holders.

15. A method of simultaneously polishing or lapping a first substrate having a work surface and a second substrate having a work surface, the method comprising:
providing a substrate holder according to claim 1;
providing an apparatus having a first polishing or lapping surface and a second polishing or lapping surface facing the first polishing or lapping surface;
disposing the first substrate in contact with the first side of the substrate holder, disposing the second substrate in contact with the second side of the substrate holder; and
contacting the first polishing or lapping surface with the work surface of the first substrate while the first substrate is on the first side of the substrate holder so to polish or lap the first substrate while also contacting the second polishing or lapping surface with the work surface of the second substrate while the second substrate is held with the second side of the substrate holder so as to polish or lap the second substrate.

16. The method of claim 15, further comprising rotating the first polishing or lapping surface while contacting the first substrate and/or rotating the second polishing or lapping surface while contacting the second substrate.

17. The method of claim 15, further comprising rotating the first polishing or lapping surface while contacting the first substrate and/or rotating the second polishing or lapping surface while contacting the second substrate; and allowing momentum transferred from the first polishing or lapping surface and/or the second polishing or lapping surface to freely rotate and/or spin the substrate holder and wafers.

18. The method of claim 15, further comprising using a slurry, an abrasive, and/or a lubricant during the polish or lap.

19. The method of claim 15, wherein the first substrate and the second substrate comprise semiconductor wafers for fabricating electronic and/or optical devices.

20. The method of claim 15, wherein the first substrate and the second substrate comprise silicon wafers for fabricating electronic devices.

21. A substrate holder for a first substrate and a second substrate, the first substrate and the second substrate each having a work surface, the substrate holder comprising:
a metal disk-shaped body having a first side and a second side on opposite sides of the body; the first side having a first recessed area sized to receive the first substrate, the depth of the first recessed area being not greater than the thickness of the first substrate; the second side having a second recessed area sized to receive the second substrate, the depth of the second recessed area being not greater than the thickness of the second substrate; so as to hold the first substrate on the first side and the second substrate on the second side so that the work surface of the first substrate faces away from and is parallel to the work surface of the second substrate.

22. A substrate holder for two or more substrates, each of the two or more substrates having a work surface, the substrate holder comprising:
a substantially rigid body having a first side and a second side on opposite sides of the body, the first side having one or more recessed areas to receive one or more of the two or more substrates, the second side having one or more recessed areas to receive one or more of the two or more substrates, wherein the work surface of the one or more substrates on the first side faces the opposite direction of the work surface of the one or more substrates on the second side.
